(19) United States
(12) Patent Application Publication
(10) Pub. No.: US 2010/0099254 A1
(43) Pub. Date: Apr. 22, 2010

(54) SEMICONDUCTOR MANUFACTURING APPARATUS, SEMICONDUCTOR DEVICE MANUFACTURING METHOD, STORAGE MEDIUM AND COMPUTER PROGRAM

(75) Inventors: Masaki Narushima, Yamanashi (JP); Yasuhiko Kojima, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Tokyo Electron Limited, Minato-ku, Tokyo (JP)

(21) Appl. No.: 12/443,983

(22) PCT Filed: Oct. 1, 2007
(86) PCT No.: PCT/JP07/69183

§ 371 Date: Apr. 2, 2009

(30) Foreign Application Priority Data
Oct. 2, 2006 (JP) 2006-271265

(51) Int. Cl. H01L 21/768; H01L 21/00

(52) U.S. Cl. 438/668; 29/25.01; 438/700; 257/E21.585; 257/E21.577

(57) ABSTRACT

A semiconductor manufacturing apparatus, when a barrier film and a copper film are formed along a recess in an insulating film by using an alloy layer of copper and addictive metal, e.g., Mn, and copper wiring is embedded therein, reduces Mn in the copper film to suppress an increase in wiring resistance. A vacuum transfer module is connected, through a load lock chamber, to a loader module for transferring a wafer with respect to a carrier. A formic acid treatment module supplying formic acid vapor as an organic acid to the wafer and a module forming a film of Cu, e.g., by CVD are connected to the vacuum transfer module to configure an apparatus manufacturing a semiconductor. The wafer W subjected to alloy layer formation and then, e.g., to annealing is transferred into the apparatus, and treatment with formic acid is performed followed by Cu film formation.

### CROSS-REFERENCE TO RELATED APPLICATIONS

This application claims the benefit of Japanese Patent Application No. 2006-271265, filed on Oct. 2, 2006, the entire disclosure of which is incorporated herein by reference.

### FIELD OF THE INVENTION

The present invention relates to a semiconductor manufacturing apparatus for forming a copper wiring by forming a recess in an insulating film and then filling copper therein, a method for manufacturing a semiconductor device, a storage medium and a computer program.

### BACKGROUND OF THE INVENTION

A multilayer wiring structure of a semiconductor device is formed by forming a metal wiring in an interlayer dielectric film. Cu (copper) is used as a material for this metal wiring due to low electromigration and low resistance, and a damascene process has been generally used as a process for forming the Cu wiring. In the damascene process, trenches for forming wiring, which is to be arranged inside an interlayer dielectric film, and via holes for forming connection wiring, which connects upper and lower wirings, are formed in the interlayer dielectric film, and Cu is buried in these recesses by a CVD method or an electrolytic plating method. When the CVD method is used, a very thin Cu seed layer is formed along the inner surfaces of the recess to facilitate the burial of Cu. Likewise, when the electrolytic plating method is used, the formation of a Cu seed layer serving as an electrode is also required. Further, since Cu is likely to diffuse into the insulating film, a barrier film made of, e.g., a laminated body of Ta/TaN, needs to be formed on the recess. Accordingly, the barrier film and the Cu seed film are formed on the surfaces of the recess by, e.g., a sputtering method.

However, as miniaturization of wiring patterns progresses, the barrier film and the seed layer, which are formed separately, are required to be formed in further reduced thicknesses. With a conventional barrier film fabrication method, however, it has been difficult to form a barrier film with high uniformity. Further, the barrier film formed by the conventional method has problems in terms of reliability of its barrier property, interface adhesion to the seed layer and the like.

In consideration of such problems, Patent Reference 1 discloses a method comprising forming an alloy layer of Cu and an additive metal, e.g., Mn (manganese), along the surface of a recess in an insulating film and then performing an annealing process. In the annealing process, Mn is diffused into the surface portion of the interlayer dielectric film and reacts with oxygen (O) which is the constituent element of the interlayer dielectric film. As a result, a barrier film of, e.g., MnOₓ (x is a natural number) or MnSiₓO_{y} (x and y are natural numbers), which are very stable compounds, is formed in a self-aligning manner, while the surface portion of the alloy layer (the opposite side to the interlayer dielectric film) becomes a Cu layer having a low Mn concentration. This self-formed barrier film is uniform and very thin, thereby contributing to solving the above-mentioned problems. In addition, in Patent Document 1, Mn moved to the surface of the alloy layer is diffused from the surface of the alloy layer through the Cu layer during a subsequent process of filling Cu and heat-treating the buried Cu.

However, in practice, when a wiring is formed by filling Cu, it is difficult to suppress the concentration of Mn in the wiring to a low level. As a result, a difference in resistance of the wiring occurs and thus, reducing the manufacturing yield. It is thought that one reason therefor is that Mn forms compounds with the impurities of the buried Cu, and the compounds remain in the Cu film.

Patent Document 1: Japanese Patent Laid-open Application No. 2005-277390: (columns 0018-0020, FIG. 1 and the like.

### SUMMARY OF THE INVENTION

In view of the above, the present invention provides a semiconductor manufacturing apparatus, a semiconductor device manufacturing method capable of reducing the amount of an additive metal in a copper film to suppress an increase in the resistance of wiring when forming a barrier film and the copper film by using an alloy layer of copper and an additive metal formed along a recess in an insulating film and then filling a copper wiring in the recess. The present invention provides a computer-readable program for executing the method and a storage medium storing the program.

In accordance with a first aspect of the present invention, there is provided a semiconductor manufacturing apparatus a semiconductor manufacturing apparatus for performing processing on a substrate which has been subjected to an alloy layer forming process of forming an alloy layer of copper and an additive metal along a wall surface of a recess in an interlayer dielectric film and to an annealing process forming a barrier layer formed of a compound of the additive metal and a constituent element of the interlayer dielectric film.

The apparatus includes a loader module at which a carrier for accommodating therein the substrate is mounted and which performs loading and unloading of the substrate into and from the carrier; a vacuum transfer chamber module having a vacuum atmosphere transfer chamber, into which the substrate is transferred from the loader module, and a substrate transfer unit provided in the transfer chamber; a surface treatment module having a processing vessel, which is airtightly connected with the transfer chamber and includes a mounting unit for mounting the substrate thereon, and a unit for supplying a vapor of a organic acid or a ketone into the processing vessel to remove the additive metal or an oxide of the additive metal on the substrate subjected to the annealing process; and a film forming module having a processing chamber, which is airtightly connected with the transfer chamber and includes therein a mounting unit for mounting the substrate thereon, and a unit for filling copper in a recess on the substrate processed in the surface treatment module.

In accordance with the present invention, the substrate transferred from the loader module may have been exposed to an atmospheric atmosphere, and thus has a native oxide film formed on the surface thereof, or the substrate transferred from the loader module may have been kept under an inert gas atmosphere.

In accordance with a second aspect of the present invention, there is provided a semiconductor manufacturing apparatus for performing processing on a substrate which has been subjected to an alloy layer forming process of forming an alloy layer of copper and an additive metal along a wall surface of a recess in an interlayer dielectric film.

The apparatus includes: a loader module at which a carrier for accommodating therein is the substrate is mounted and which performs loading and unloading of the substrate into and from the carrier; a vacuum transfer chamber module having a vacuum atmosphere transfer chamber, into which the substrate is transferred from the loader module, and a substrate transfer unit provided in the transfer chamber; and an annealing module having a process vessel, which is airtightly connected with the transfer chamber and includes therein a mounting unit for mounting the substrate thereon, and an annealing unit for performing an annealing process on the substrate subjected to the alloy layer forming process to form a barrier layer formed of a compound of the additive metal and a constituent element of the interlayer dielectric film.

The apparatus further includes a surface treatment module having a processing vessel, which is airtightly connected with the transfer chamber and includes a mounting unit for mounting the substrate thereon, and a unit for supplying a vapor of a organic acid or a ketone into the processing vessel to remove the additive metal or an oxide of the additive metal on the substrate subjected to the annealing process; and a film forming module having a processing chamber, which is airtightly connected with the transfer chamber and includes therein a mounting unit for mounting the substrate thereon, and a unit for filling copper in a recess on the substrate processed in the surface treatment module.

The organic acid may be carboxylic acid. Further, the substrate is preferably heated to a temperature in the range from 150° C. to 450° C. The additive metal is a metal preferably selected from the group consisting of Mn, Nb, Cr, V, Y, Tc and Re. The copper filling unit in the film forming module preferably performs a copper film formation by a CVD method or a sputtering method.

Further, thee apparatus may further includes an oxidation module having: a processing chamber, which is airtightly connected with the transfer chamber and includes therein a mounting unit for mounting the substrate thereon; and a unit for supplying a processing gas into the processing chamber to oxidize the substrate annealing subjected to annealing process before transferring the substrate into the surface treatment module.

In accordance with a third aspect of the present invention, there is provided a method for manufacturing a semiconductor device.

The method includes the steps of: (a) forming an alloy layer of copper and an additive metal along a wall surface of a recess in an interlayer dielectric film; (b) performing an annealing process for forming a barrier layer formed of a compound of the additive metal and constituent elements of the interlayer dielectric film; (c) performing surface treatment on the substrate by supplying a vapor of an organic acid or a ketone to the surface of the substrate in a vacuum atmosphere to remove the additive metal or an oxide of the additive metal formed on the substrate; and (d) filling copper in the recess on the substrate while keeping the substrate under a vacuum atmosphere.

Step (b) of performing the annealing process may be performed in a vacuum atmosphere, and then the substrate is preferably subjected to step (c) of performing the surface treatment while being kept in a vacuum atmosphere. Further, the substrate which has been subjected to step (b) of performing the annealing process is preferably kept under an inert gas atmosphere before step (c) of performing the surface treatment.

In accordance with a fourth aspect of the present invention, there are a computer program operated on a computer and a storage medium storing the computer program. The computer program has steps for executing the semiconductor device manufacturing method in accordance with the present invention.

A barrier layer formed of a compound of the additive metal and the constituent elements of the insulating film can be formed by annealing the alloy layer of copper and additive metal formed along the surface of a recess in an insulating film, but in the annealing process, the additive metal also moves to the surface portion of the alloy layer. In accordance with the present invention, the additive metal is removed by an organic acid or a ketone in a non-converted state or after conversion to an oxide. Thus, the amount of additive metal included in Cu of the surface portion of the self-formed barrier film can be reduced, and if an oxide of the additive metal is formed on the surface, the oxide can also be removed. As a result, the amount of the additive metal in Cu after the Cu filling process can be reduced, thus suppressing an increase in resistance of the wiring.

### BRIEF DESCRIPTION OF THE DRAWINGS

FIG. 1 is a configuration view of a substrate processing system including a semiconductor manufacturing apparatus in accordance with an embodiment of the present invention;

FIG. 2 is a plane view of the semiconductor manufacturing apparatus;

FIG. 3 is a cross-sectional view showing an example of a formic acid processing module included in the semiconductor manufacturing apparatus;

FIG. 4 is a cross-sectional view showing an example of a CuCVD module included in the semiconductor manufacturing apparatus;

FIGS. 5A to 5F provide cross-sectional views showing the surface of a wafer which is processed by the substrate processing system;

FIGS. 6A to 6D provide cross-sectional views showing the change of the surface of the wafer;

FIG. 7 is a plan view showing another example of the semiconductor manufacturing apparatus;

FIG. 8 is a plane view showing another example of the semiconductor manufacturing apparatus; and

FIG. 9 is a plane view showing another example of the semiconductor manufacturing apparatus.

### DETAILED DESCRIPTION OF THE EMBODIMENTS

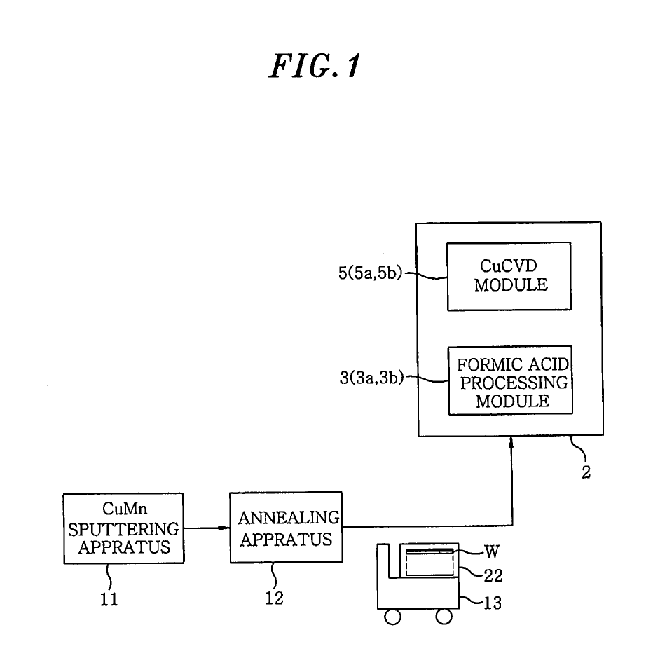

First, a substrate processing system in a clean room, which includes a semiconductor manufacturing apparatus in accordance with the present invention, will be described with reference to FIG. 1. The substrate processing system, which will be described in detail later, is a system for forming a wiring on the surface of a semiconductor wafer W as a substrate. In FIG. 1, reference numeral 11 denotes a CuMn sputtering apparatus for forming a film of an alloy of Cu (copper) and manganese (Mn) on the wafer W. In FIG. 1, reference numeral 12 denotes an annealing apparatus for annealing the formed alloy film by an inert gas, e.g., nitrogen (N₂). In the annealing apparatus, e.g., one wafer W is processed each time for about 10 to 60 minutes. In the present embodiment, the CuMn sputtering apparatus 11 and the annealing apparatus 12 are apparatuses for performing processes performed before processing which is performed by the semiconductor manufacturing apparatus in accordance with an embodiment of the present invention.

In FIG. 1, reference numeral 2 denotes a semiconductor manufacturing apparatus in accordance with the embodiment of the present invention, which has a multi-chamber system and performs processing on the wafer W in a vacuum atmosphere. The semiconductor manufacturing apparatus 2 includes formic acid processing modules 3 for supplying formic acid as an organic acid to the wafer W and CuCVD modules 5 for forming a Cu film on the wafer W. The configuration of the semiconductor manufacturing apparatus 2 will be explained in further detail later.

In FIG. 1, reference numeral 13 denotes a transfer robot which transfers a carrier 22 accommodating therein a plurality of, e.g., 25 wafers W, in a clean room. As indicated by arrows in FIG. 1, the transfer robot 13 transfers the carrier 22 from the CuMn sputtering apparatus 11, to the annealing apparatus 12 and then to the semiconductor manufacturing apparatus 2 in this sequence. The carrier 22 is, e.g., a sealed carrier (referred to as FOUP), and the inside thereof is kept under an atmospheric atmosphere or an insert gas atmosphere. That is, the transfer of the carrier 22 between these apparatuses by the transfer robot 13 is performed in an atmospheric atmosphere or an inert gas atmosphere.

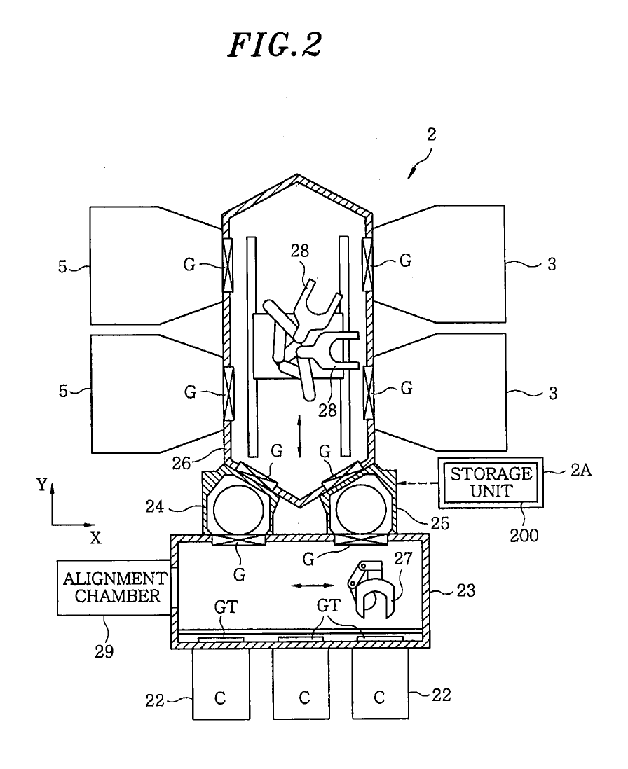

A detailed configuration of the semiconductor manufacturing apparatus 2 will now be explained with reference to FIG. 2. The semiconductor manufacturing apparatus 2 includes: a first transfer chamber 23 which is a loader module for loading and unloading of a substrate; load lock chambers 24 and 25; and a second transfer chamber 26 which is a vacuum transfer chamber module. On the front wall of the first transfer chamber 23, gate doors GT which are connected to the sealed carriers 22 and opened or closed along with lids of the carriers 22 are provided. The formic acid processing modules 3 as a surface treatment module and the CuCVD modules 5 are airtightly connected to the second transfer chamber 26.

Further, an alignment chamber 29 is provided on a lateral side of the first transfer chamber 23. Each of the load lock chambers 24 and 25 includes a vacuum pump and a leak valve (not shown), and the inside of each of the load lock chambers 24 and 25 can be switched between an atmospheric atmosphere and a vacuum atmosphere. That is, since the first transfer chamber 23 and the second transfer chamber 26 are kept under the atmospheric atmosphere and the vacuum atmosphere, respectively, the load lock chambers 24 and 25 serve to adjust the atmosphere for the transfer of the wafer W between the first and second transfer chambers 23 and 26. Furthermore, notation G in FIG. 2 indicates gate valves (partition valves) which separate the load lock chambers 24 and 25 from the first transfer chamber 23 or the second transfer chamber 26, or separate the second transfer chamber 26 from the modules 3 or 5.

The first and second transfer chambers 23 and 26 include a first transfer unit 27 and a second transfer unit 28, respectively. The first transfer unit 27 is a transfer arm for transferring the wafer W between the carrier 22 and the load-lock chamber 24 or 25 and between the first transfer chamber 23 and the alignment chamber 29. The second transfer unit 28 is a transfer arm for transferring the wafer W between the load-lock chamber 24 or 25 and the formic acid processing modules 3 or the CuCVD modules 5.

As shown in FIG. 2, the semiconductor manufacturing apparatus 2 includes a controller 2A which is e.g., a computer. The controller 2A includes a data processing module formed with a program, a memory, a CPU, and the like. The program includes instructions such that it transmits a control signal from the controller 2A to each unit of the semiconductor manufacturing apparatus 2 to perform steps which will be described later. Further, the memory having a region in which processing parameter values, e.g., a processing pressure, a processing temperature, a processing time, gas flow rate, power values and the like are stored. Therefore, when the CPU executes each instruction, these processing parameter values are read, and control signals corresponding to the parameter values are transmitted to each unit of the semiconductor manufacturing apparatus 2. The program (also including a program relating to the display or the input operation of the processing parameters) is stored in a storage unit 200, i.e., a computer storage medium, such as a flexible disc, a compact disc, a hard disc, magneto-optical disc (MO) or the like and is installed in the controller 2A.

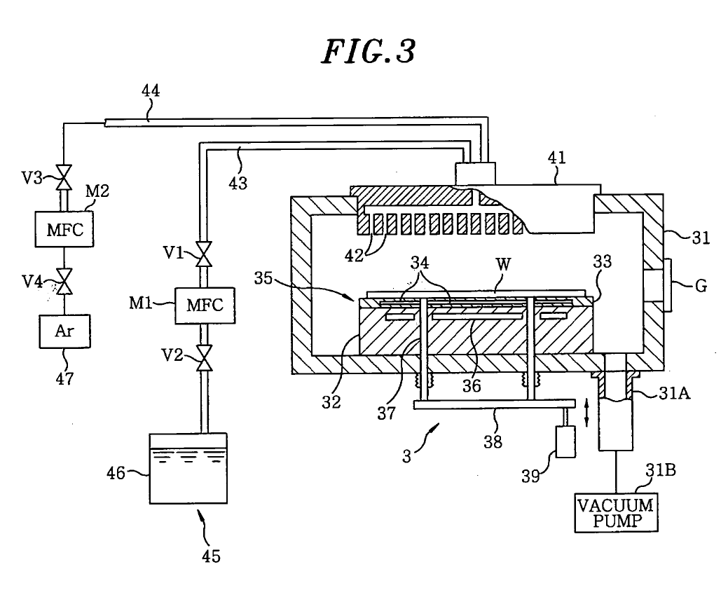

The configuration of the formic acid processing module 3 which is included in the semiconductor manufacturing apparatus 2 is described with reference to FIG. 3. Reference numeral 31 in FIG. 3 is a processing vessel configured as a vacuum chamber made of, e.g., aluminum. Disposed on the bottom portion of the processing vessel 31 is a mounting table 32 for mounting thereon a wafer W. An electrostatic chuck 35 having a dielectric layer 33 in which a chuck electrode 34 is embedded is provided on the surface portion of the mounting table 32, and a chuck voltage is applied to the electrostatic chuck 35 from a power supply unit (not shown). Further, a heater 36 as temperature control means is provided in the mounting table 32. The mounting table 32 is also provided with elevating pins 37 configured to be protruded above and retracted below a mounting surface. The elevating pins 37 move the wafer W up and down to load/unload the wafer W from/to the second transfer unit 28. The elevating pins 37 are connected to a driving unit 39 via a supporting member 38, so that they are moved up and down by operating the driving unit 39.

A gas shower head 41 is disposed at the ceiling portion of the processing vessel 31 to face the mounting table 32. The gas shower head 41 is provided with a number of gas supply holes 42 in its bottom surface. Connected to the gas shower head 41 are a first gas supply line 43 for supplying a source material gas and a second gas supply line for supplying a dilution gas. The source material gas and the dilution gas supplied from the gas supply lines 43 and 44 are mixed together, and this gaseous mixture is supplied into the processing vessel 31 through the gas supply holes 42.

The first gas supply line 43 is connected to a source material gas supply source 45 via a valve V1, a mass flow controller (MFC) M1 serving as a gas flow rate controller and a valve V2. The source material gas supply source 45 includes a reservoir 46 made of stainless steel, and carboxylic acid as an organic acid, e.g., formic acid, which produces a highly volatile metal compound and is capable of reducing metal oxide, is stored in the reservoir 46. Further, the second gas supply line 44 is coupled to a dilution gas supply source 47 for supplying the dilution gas, e.g., Ar (argon) gas, via a valve V3, a mass flow controller (MFC) M2 and a valve V4.

One end of a gas exhaust line 31A is connected to the bottom portion of the processing vessel 31, and the other end of the gas exhaust line 31A is coupled to a vacuum pump 31B serving as a vacuum exhaust unit.

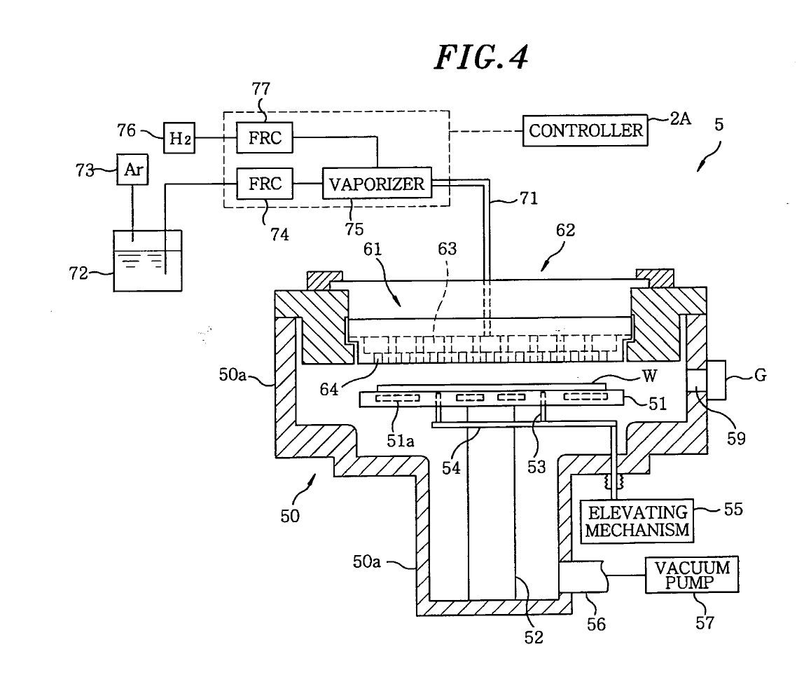

The configuration of the CuCVD module for forming a Cu film, which is included in the semiconductor manufacturing apparatus 2, is explained with reference to FIG. 4. Reference numeral 50 in FIG. 4 showing the CuCVD module 5 indicates a processing vessel (a vacuum chamber) made of, e.g., aluminum. The processing vessel 50 has a mushroom shape formed of an upper large-diameter cylindrical portion 50a and a lower small-diameter cylindrical portion 50b and is provided with a heater for heating the inner wall thereof. The processing vessel 50 includes a stage 51 for horizontally mounting a wafer W thereon, and the stage 51 is supported on a supporting member 52 disposed on the bottom portion of the small-diameter cylindrical portion 50b.

The stage 51 includes a heater 51a as means for controlling the temperature of the wafer W. The stage 51 is also provided with a plurality of, e.g., three (for convenience, only two are shown in FIG. 4) of elevating pins 53 configured to be protruded above and retracted below the surface of the stage 51. The elevating pins 53 move the wafer W up and down to load/unload the wafer W from/to the second transfer unit 28. The elevating pins 53 are connected to an elevating mechanism 55 outside the processing vessel 50 via a supporting member 54. One end of a gas exhaust line 56 is connected to the bottom portion of the processing vessel 50, and the other end of the gas exhaust line 56 is connected to a vacuum pump 57. At the sidewall of the large-diameter cylindrical portion 50a of the processing vessel 50, a transfer port 59 which is opened and closed by a gate valve G is formed.

Further, at the ceiling portion of the processing vessel 50, an opening 61 is formed, and a gas shower head 62 is provided to close the opening 61 and to face the stage 51. The gas shower head 62 includes a gas chamber 63 and gas supply holes 64 for supplying two kinds of gases. The gases supplied to the gas chamber 63 are supplied into the processing vessel 50 through the gas supply holes 64.

Connected to the gas chamber 63 is a source material gas supply line 71, and a source material reservoir 72 is connected upstream of the source material gas supply line 71. In the source material reservoir 72, Cu(hfac)TMVS which is an organic compound (complex) of copper as a source material (precursor) for forming a copper film is stored in a liquid state. The source material reservoir 72 is connected to a pressurizing unit 73, so that Cu(hfac)TMVS can be pressed out toward the gas shower head 62 by pressurizing the inside of the source material reservoir 72 with argon gas supplied from the pressurizing unit 73. In addition, in the source material gas supply line 71, a flow rate controller (FRC) 74 including a liquid flow controller and/or a valve, and a vaporizer 75 for vaporizing Cu(hfac)TMVS are disposed sequentially from the upstream side. The vaporizer 75 functions to vaporize Cu(hfac)TMVS by contacting and mixing it with a carrier gas (hydrogen gas) supplied from a carrier gas source 76 and to supply the gaseous mixture to the gas chamber 63. In FIG. 4, reference numeral 77 is a flow rate controller (FRC) for controlling the flow rate of the carrier gas.

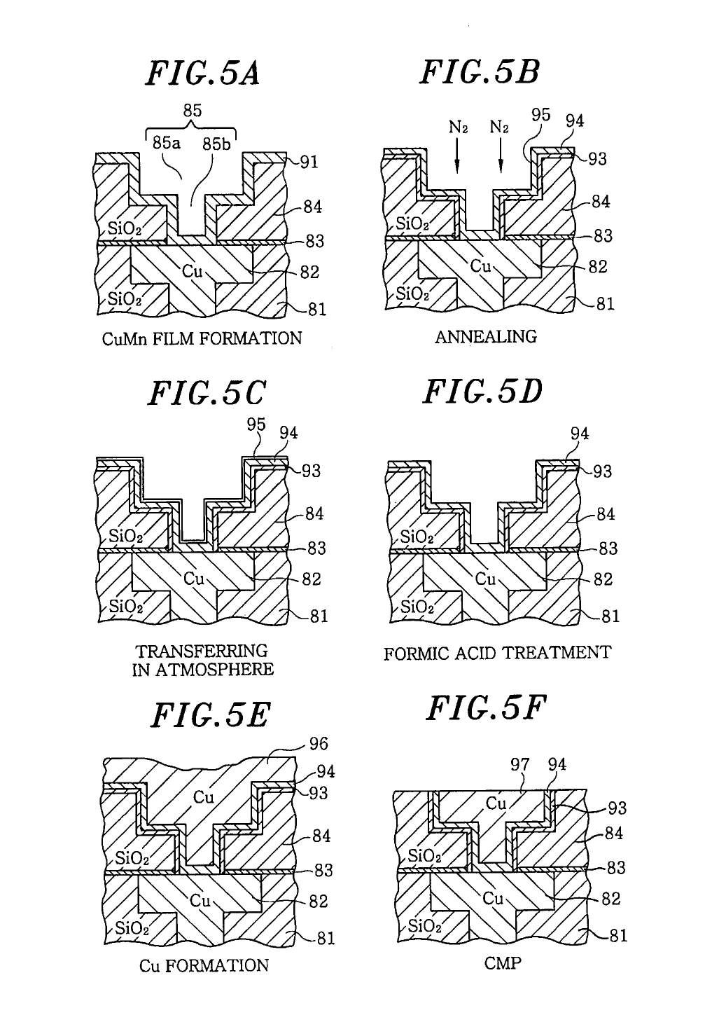

Next, a wafer W which is processed by the above-described substrate processing system is described with reference to FIGS. 5A to 5F. Before the wafer W is transferred into this substrate processing system, an underlayer wiring 82 is formed on the surface of the wafer W by filling Cu in an interlayer dielectric film 81 made of SiO₂ (silicon oxide), and an interlayer dielectric film 84 made of SiO₂ (silicon oxide) is formed on the interlayer insulting film 81 via a barrier film 83. Further, a recess 85 formed of a trench 85a and a via hole 85b is formed in the interlayer dielectric film 84, and the underlayer wiring 82 is exposed at the recess 85. A process to be described below is a process for forming an upper wiring electrically connected with the underlayer wiring 82 by filling Cu in the recess 85. Although the interlayer dielectric films have been exemplified by the SiO₂ films, a SiOCH film or the like may be employed.

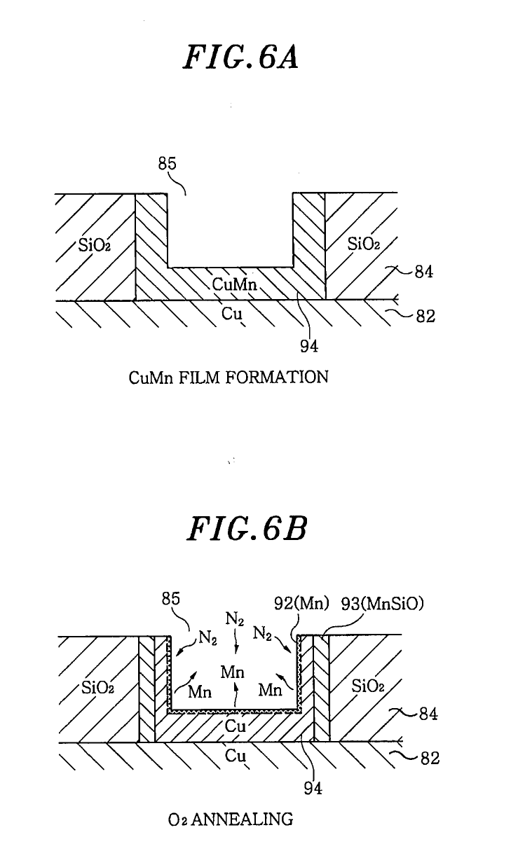

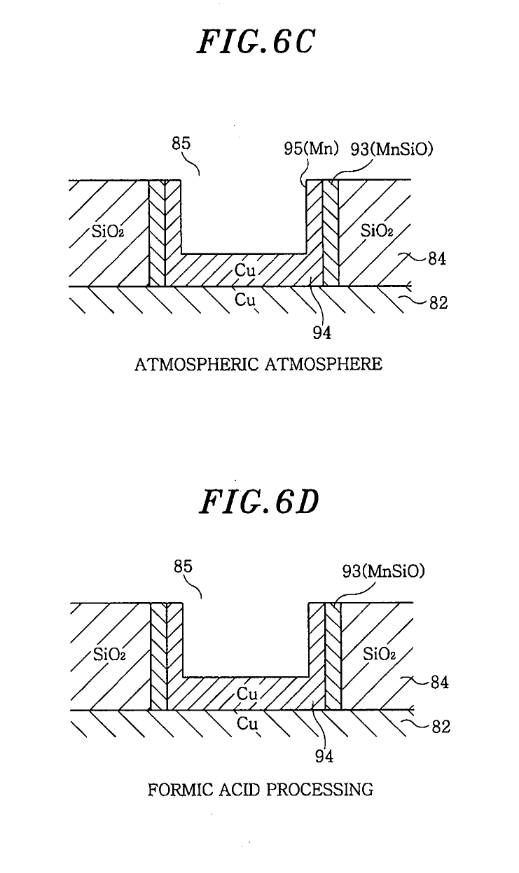

Hereinafter, a semiconductor manufacturing process is described with reference to FIGS. 5A and 6D. FIGS. 5A to 5F illustrate cross-sectional views showing a manufacturing process of a semiconductor device formed on the surface of the wafer W. FIGS. 6A to 6D illustrate the pattern transition occurring in the recess 85 when the wafer W is processed by each apparatus in the substrate processing system. In FIGS. 6A to 6D, the structure of the recess 85 is simplified to focus on the pattern transition.

First, the carrier 22 is transferred to the CuMn sputtering apparatus 11 by the transfer robot 13. On the surface of each of the wafers W sequentially unloaded from the carrier 22, as shown in FIG. 5A, a CuMn film 91 which is an alloy layer of Cu and Mn is formed, so that the inside of the recess 85 is covered with the CuMn film 91 (FIG. 6A). The CuMn film 91 has a film thickness in the range, e.g., from 3 to 100 nm, and a Mn content in the range, e.g., from 1 to 10 atom %.

After formation of the CuMn film 91, the wafer W is loaded into the annealing apparatus 12. As shown in FIG. 5B, the surface of the wafer W in the annealing apparatus 12 is supplied with N₂ gas in a heated state to anneal the CuMn film 91. With this annealing, Mn is diffused to the surface of the interlayer dielectric film. Therefore, as shown in FIG. 6B, the separation of Mn 92 from Cu 94 film occurs and some of the Mn included in the CuMn film 91 moves toward the surface of the CuMn film 91.

Mn diffused to the interface between the CuMn film 91 and the SiO₂ film 84 reacts with SiO₂ to form a MnSiₓO_{y} film 93. The MnSiₓO_{y} film 93 functions as a barrier layer for preventing Cu from diffusing to the SiO₂ film 84 when Cu is buried in the recess 85.

After the annealing process, the wafer W is returned to the carrier 22, and then the carrier 22 is transferred to the semiconductor manufacturing apparatus 2 by the transfer robot 13. At this time, the atmosphere inside the carrier 22 is an atmospheric atmosphere or an inert gas atmosphere as described above, but in this embodiment, the inside of the carrier is kept under the atmospheric atmosphere. During the transfer process, the Mn 92 which moved to the surface of the recess 85 can be oxidized by an oxygen in the atmospheric atmosphere to be a MnOₓ (manganese oxide film) 95 as shown in FIGS. 5C and 6C.

Subsequently, the carrier 22 is transferred to the semiconductor manufacturing apparatus 2 by the transfer robot 13 and is connected to the first transfer chamber 23. Then, the gate door GT and the lid of the carrier 22 are opened simultaneously, and the wafer W in the carrier 22 is loaded into the first transfer chamber 23 by the first transfer unit 27. Then, the wafer W is loaded into the alignment chamber 29, and the direction or eccentricity of the wafer W is adjusted therein. Then, the wafer W is transferred into the load-lock chamber 24 (or 25). Once the internal pressure of the load-lock chamber 24 is adjusted, the wafer W is loaded into the second transfer chamber 26 from the load-lock chamber 24 by the second transfer unit 28. Subsequently, a gate valve G of one of the formic acid processing modules 3 is opened, and the wafer W is loaded into the formic acid processing module 3 by the second transfer unit 28.

After the wafer W is loaded into the processing vessel 31 of the formic acid processing module 3, the inside of the processing vessel 31 is exhausted to a specific vacuum level by the vacuum pump 31B, and then the valves V1 to V4 are opened. Herein, although the gas supply lines 43 and 44 are described as being opened or closed individually by the valves V1 to V4 for the simplicity of explanation, an actual gas line system is actually more complicated and the opening and closing of the gas supply lines 43 and 44 is carried out by stop valves or the like. If the inside of the processing vessel 31 is allowed to communicate with the inside of the reservoir 46 by opening the first gas supply line 43, a vapor (source material gas) in the reservoir 46 is introduced into the gas shower head 41 via the first gas supply line 43 in a state of its flow rate being regulated by the mass flow controller M1.

Meanwhile, Ar gas used as a dilution gas is supplied into the gas shower head 41 from the dilution gas supply source 47 through the second gas supply line 44 in the state of its flow rate being regulated by the mass flow controller M2. In the gas shower head 41, the Ar gas is mixed with the formic acid vapor, and the gaseous mixture is supplied into the processing vessel 31 through the gas supply holes 42 of the gas shower head 41 and comes in contact with the wafer W. At this time, the wafer W is heated by the heater 36 at a temperature in the range, e.g., from 150° C. to 450° C., preferably in the range from 150° C. to 300° C., and the processing pressure inside the processing vessel 31 is maintained in the range, e.g., from 10 to 10⁵ Pa.

In the present embodiment, the MnOₓ film 95 as a metal oxide is formed on the surface of the recess 85 by the atmospheric transfer described above. For this reason, when formic acid is supplied, MnOₓ formed on the surface of the recess 85 is removed as shown in FIG. 5D by the reducing action of formic acid and the etching action of the MnOₓ film 95 serving as the metal oxide. It is thought that, since formic acid and the metal form a highly volatile compound, the reducing action thereof removes Mn from the film. As described above, since Mn diffuses toward the surface of the recess 85, Mn remaining without reaction with O₂ is etched together with MnOₓ. Therefore, as shown in FIG. 6D, the Cu film 94 is exposed to the surface of the recess 85. Further, since Mn is more likely to bond with oxygen than with Cu, Mn is removed together with oxygen, and the amount of Cu removed is small.

After the formic acid processing, the valves V1 to V4 are closed, and the supply of the formic acid vapor and the Ar gas is stopped. Then, the gate valve G is opened, and the wafer W is transferred to the second transfer unit 28 by the elevating pins 37. Then, a gate valve of one of the CuCVD modules 5 is opened, and the wafer W is transferred into the processing vessel 50 of the CuCVD module 5 by the second transfer unit 28.

The wafer W transferred into the processing vessel 50 of the CuCVD module 5 is transferred from the second transfer unit 28 to the elevating pins 53 and mounted on the stage 51. Then, the wafer W is heated by the heater 51a of the stage 51 at a temperature in the range, e.g., from about 100° C. to 250° C.

Thereafter, a Cu(hfac)TMVS gas of, e.g., 0.5 g/min (converted to mass), is supplied into the processing vessel 50 together with a carrier gas (hydrogen gas) having a flow rate of, e.g., 200 sccm, whereby Cu 96 is buried in the recess 85 as shown in FIG. 5E.

For example, after the lapse of a given time period, heating of the wafer W and supplying of the Cu(hfac)TMVS gas and the carrier gas are stopped, the gate valve G is opened, and the second transfer unit 28 gets into the processing vessel 50. In the meantime, the elevating pins 53 are elevated to unload the wafer W, which has been subjected to the formic acid processing, to the second transfer unit 28, and the second transfer unit 28 then transfers the wafer W to the first transfer unit 27 via the load-lock chamber 24 or 25. Then, the wafer W is returned back into the carrier 22 by the first transfer unit 27.

Thereafter, the wafer W processed in the semiconductor manufacturing apparatus 2 is subjected to CMP (Chemical Mechanical Polishing). By the CMP process, as shown in FIG. 5F, the Cu 96 which overflowed from the recess 85, and the Cu film 94 and the MnSiₓO_{y} film 93 formed on the surface of the wafer W are removed, whereby an upper layer wiring 97 electrically connected to the underlayer wiring 82 is formed.

By the semiconductor manufacturing apparatus 2 in accordance with the above-described embodiment, the wafer W having formed thereon the MnSixOy film 93, which is formed by annealing MnCu alloy and is called a self-formed barrier film, is transferred in, e.g., an atmospheric atmosphere, and then its surface is treated by the formic acid vapor. Accordingly, Mn included in the Cu film 94 formed on the side surface of the self-formed barrier film is oxidized in this embodiment, and this oxidized and non-oxidized Mn are removed by etching in the formic acid treatment. For this reason, Mn in the Cu film 94 can be reduced and the MnOₓ as an oxide is also removed. Accordingly, the adhesion of the upper layer wiring 97 to the underlying Cu film 94 can be increased and, the increase in the resistance of a wiring formed by filling Cu in a subsequent process can be suppressed. Further, e.g., when the inside of the carrier 22 is kept under an inert gas atmosphere, Mn included in the Cu film 94 is not necessarily oxidized. In this case, the Mn can be removed by etching in formic acid treatment, and the same effect as in the case in which the Mn is oxidized in the carrier 22 kept under an atmospheric atmosphere can be obtained.

Further, Mn, Nb, Cr, V, Y, Tc, Re or the like may be used as the additive metal for forming an alloy with Cu. In addition, although formic acid is used as the organic acid to perform the surface treatment in the above-described embodiment, an organic acid such as carboxylic acid, e.g., acetic acid, or a ketone may be used, and in this case, the same effect as the use of formic acid can be obtained.

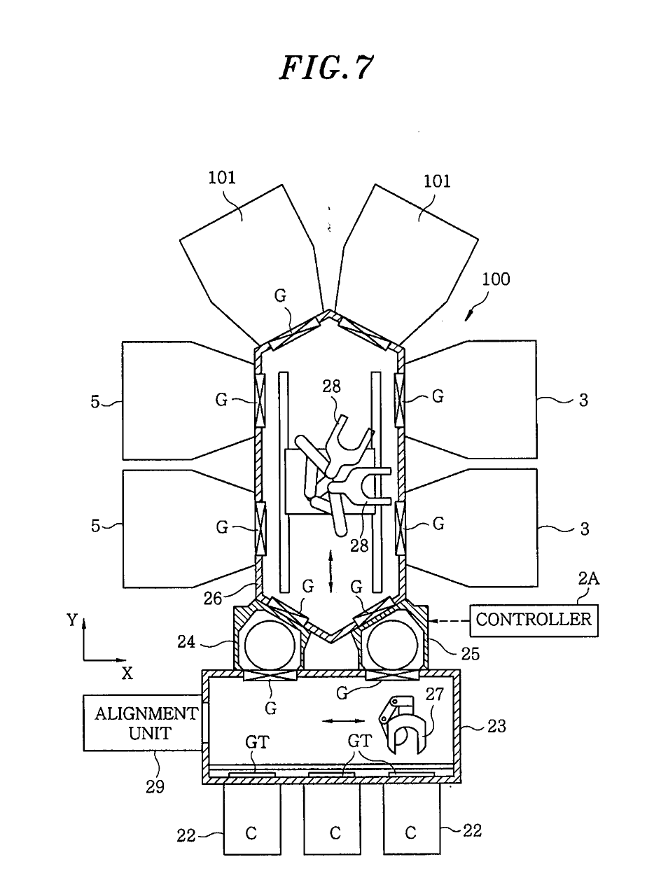

Hereinafter, other examples of a semiconductor manufacturing apparatus in accordance with the present invention will be described with reference to FIGS. 7 to 9. In the semiconductor manufacturing apparatuses 100 shown in FIGS. 7 to 9, like parts are indicated by like reference numerals as used in the above-described semiconductor manufacturing apparatus 2. The difference of the semiconductor manufacturing apparatus 100 from the semiconductor manufacturing apparatus 2 in accordance with the above-described embodiment is described. In the embodiment of FIG. 7, the second transfer chamber 26 includes oxidation modules 101 in addition to the formic acid processing modules 3 and the CuCVD modules 5. The oxidation module 101 has approximately the same configuration as that of the above-described formic acid processing module 3, but, e.g., oxygen gas is used as a processing gas which is supplied into a processing vessel of the oxidation module. Once the wafer W is loaded into the processing vessel in the oxidation module 101, it is supplied with oxygen gas while being heated, whereby the surface thereof is oxidized to form the MnOₓ film 95.

The second transfer unit of the second transfer chamber 26 transfers the loaded wafer W to the oxidation module 101, to the formic acid processing module 3 and then to the CuCVD module 5 in this sequence. In the semiconductor manufacturing apparatus 100 thus configured, since the surface of the wafer W which is loaded into the formic acid processing module 3 is forcedly oxidized by the oxidation module 101, it is thought that Mn in the Cu film has been oxidized. Accordingly, in the formic acid processing module 3, MnOₓ is removed by etching in the formic acid treatment, and thus the semiconductor manufacturing apparatus 100 in FIG. 7 can achieve the same effects as those of the above-described semiconductor manufacturing apparatus 2.

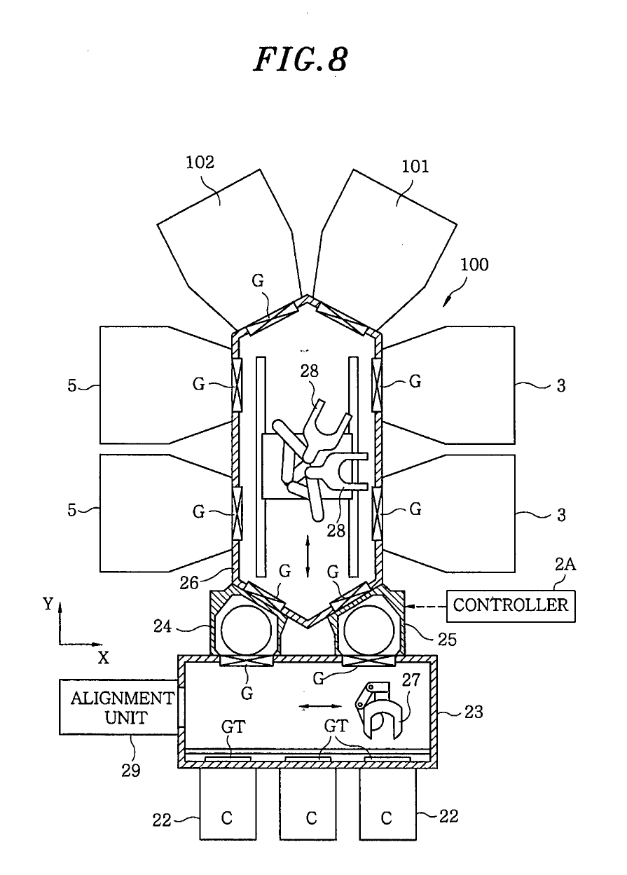

In the embodiment of FIG. 8, an annealing module 102 in addition to the formic acid processing modules 3, the CuCVD modules 5 and the oxidation module 101 are connected to the second transfer chamber 26. The annealing module 102 corresponds to the annealing apparatus 12 of the above-described substrate processing system and has approximately the same configuration as that of the formic acid processing module 3. However, e.g., inert gas such as N₂ gas is used as a processing gas which is supplied into the processing vessel of the annealing module 102. Once the wafer W is loaded into the processing vessel of the annealing module 102, it is supplied with N₂ gas while being heated, whereby the separation of the CuMn film 91 is carried out as described above. Accordingly, the MnSiₓO_{y} film 93 which is a self-formed barrier film can be obtained. In this embodiment, after the CuMn film 91 (an alloy layer) is formed on the wafer W, the wafer W is loaded into the semiconductor manufacturing apparatus 100 and annealed in the annealing module 102.

The second transfer unit 28 of the second transfer chamber 26 transfers the loaded wafer W to the annealing module 102, to the oxidation module 101, to the formic acid processing module 3 and then to the CuCVD module 5 in this sequence. The semiconductor manufacturing apparatus 100 thus configured can also achieve the same effects as those of the semiconductor manufacturing apparatus 2 shown in FIG. 2 or FIG. 7.

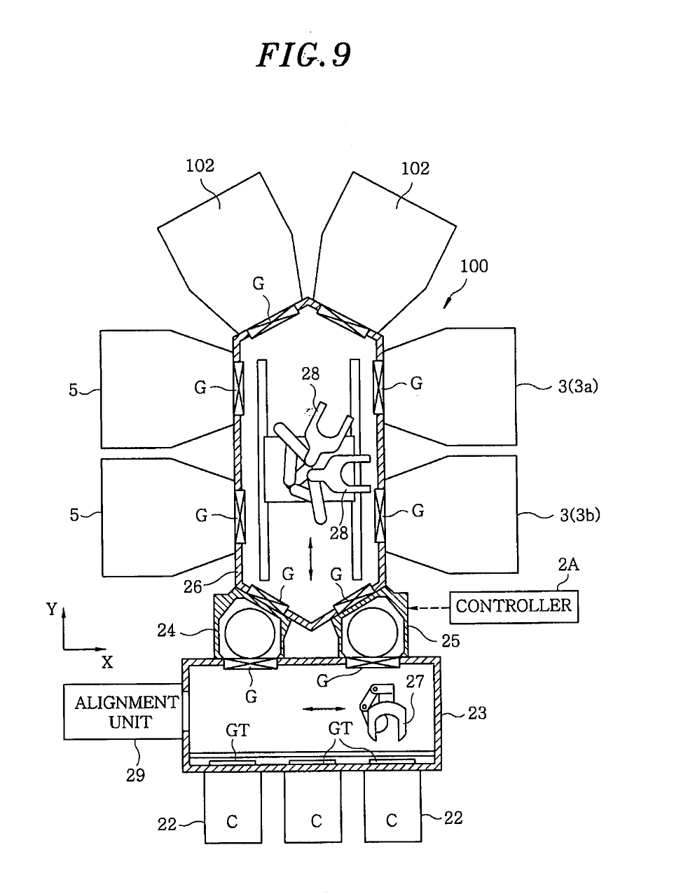

In the embodiment of FIG. 9, the formic acid processing modules 3, the CuCVD modules 5 and the annealing modules 102 are connected to the second transfer chamber 26, but the oxidation module 101 is not connected thereto. That is, in this embodiment, the oxidation module 101 in the embodiment of FIG. 8 is not provided, and Mn in the surface of the wafer W is removed by etching in the formic acid processing module 3. The semiconductor manufacturing apparatus 100 thus configured can also achieve the same effects as those of the semiconductor manufacturing apparatus 2 shown in FIG. 2 or FIG. 7.

In the foregoing, the numbers of the modules connected to the second transfer chamber 26 are not limited to those in the above-described embodiments and can be suitably determined in consideration of processing time in each of the modules. Further, although the wafer W has been described herein as the substrate by way of example, the present invention may also be applied to glass substrates, LCD substrates, ceramic substrates and the like.

What is claimed is:

1. A semiconductor manufacturing apparatus for performing processing on a substrate which has been subjected to an alloy layer forming process of forming an alloy layer of copper and an additive metal along a wall surface of a recess in an interlayer dielectric film and to an annealing process forming a barrier layer formed of a compound of the additive metal and a constituent element of the interlayer dielectric film, the apparatus comprising:
a loader module at which a carrier for accommodating therein the substrate is mounted and which performs loading and unloading of the substrate into and from the carrier;
a vacuum transfer chamber module having a vacuum atmosphere transfer chamber, into which the substrate is transferred from the loader module, and a substrate transfer unit provided in the transfer chamber;
a surface treatment module having a processing vessel, which is airtightly connected with the transfer chamber and includes a mounting unit for mounting the substrate thereon, and a unit for supplying a vapor of a organic acid or a ketone into the processing vessel to remove the additive metal or an oxide of the additive metal on the substrate subjected to the annealing process; and
a film forming module having a processing chamber, which is airtightly connected with the transfer chamber and includes therein a mounting unit for mounting the substrate thereon, and a unit for filling copper in a recess on the substrate processed in the surface treatment module.

2. The apparatus of claim 1, wherein the substrate transferred from the loader module has been exposed to an atmospheric atmosphere, and thus has a native oxide film formed on the surface thereof.

3. The apparatus of claim 1, wherein the substrate transferred from the loader module has been kept under an inert gas atmosphere.

4. A semiconductor manufacturing apparatus for performing processing on a substrate which has been subjected to an alloy layer forming process of forming an alloy layer of copper and an additive metal along a wall surface of a recess in an interlayer dielectric film, the apparatus comprising:
a loader module at which a carrier for accommodating therein is the substrate is mounted and which performs loading and unloading of the substrate into and from the carrier;
a vacuum transfer chamber module having a vacuum atmosphere transfer chamber, into which the substrate is transferred from the loader module, and a substrate transfer unit provided in the transfer chamber;
an annealing module having a process vessel, which is airtightly connected with the transfer chamber and includes therein a mounting unit for mounting the substrate thereon, and an annealing unit for performing an annealing process on the substrate subjected to the alloy layer forming process to form a barrier layer formed of a compound of the additive metal and a constituent element of the interlayer dielectric film;
a surface treatment module having a processing vessel, which is airtightly connected with the transfer chamber and includes a mounting unit for mounting the substrate thereon, and a unit for supplying a vapor of a organic acid or a ketone into the processing vessel to remove the additive metal or an oxide of the additive metal on the substrate subjected to the annealing process; and
a film forming module having a processing chamber, which is airtightly connected with the transfer chamber and includes therein a mounting unit for mounting the substrate thereon, and a unit for filling copper in a recess on the substrate processed in the surface treatment module.

5. The apparatus of claim 1, wherein the organic acid is carboxylic acid.

6. The apparatus of claim 1, wherein the surface treatment module includes a heating unit for heating the substrate at a temperature in the range from 150° C. to 450° C.

7. The apparatus of claim 1, wherein the additive metal is a metal selected from the group consisting of Mn, Nb, Cr, V, Y, Tc and Re.

8. The apparatus of claim 1, wherein the copper filling unit in the film forming module performs a copper film formation by a CVD method or a sputtering method.

9. The apparatus claim 1, which further comprises an oxidation module including: a processing chamber, which is airtightly connected with the transfer chamber and includes therein a mounting unit for mounting the substrate thereon; and a unit for supplying a processing gas into the processing chamber to oxidize the substrate annealing subjected to annealing process before transferring the substrate into the surface treatment module.

10. A method for manufacturing a semiconductor device, the method comprising the steps of:
(a) forming an alloy layer of copper and an additive metal along a wall surface of a recess in an interlayer dielectric film;
(b) performing an annealing process for forming a barrier layer formed of a compound of the additive metal and constituent elements of the interlayer dielectric film;
(c) performing surface treatment on the substrate by supplying a vapor of an organic acid or a ketone to the surface of the substrate in a vacuum atmosphere to remove the additive metal or an oxide of the additive metal formed on the substrate; and
(d) filling copper in the recess on the substrate while keeping the substrate under a vacuum atmosphere.

11. The method of claim 10, wherein the substrate which has been subjected to step (b) of performing the annealing process is exposed to an atmospheric atmosphere to form a native oxide film on the surface thereof before step (c) of performing the surface treatment.

12. The method of claim 10, wherein the substrate which has been subjected to step (b) of performing the annealing process is kept under an inert gas atmosphere before step (c) of performing the surface treatment.

13. The method of claim 10, wherein step (b) of performing the annealing process is performed in a vacuum atmosphere, and then the substrate is subjected to step (c) of performing the surface treatment while being kept in a vacuum atmosphere.

14. The method of claim 10, wherein step (c) of performing the surface treatment is preformed by heating the substrate at a temperature in the range from 150° C. to 450° C.

15. The method of claim 10, further comprising, a step of oxidizing the substrate by supplying a processing gas onto the substrate between step (b) of performing the annealing process and step (c) of performing the surface treatment.

16. A storage medium storing a computer program for executing a semiconductor device manufacturing method on a computer, the method comprising the steps of:
(a) forming an alloy layer of copper and an additive metal along a wall surface of a recess in an interlayer dielectric film;
(b) performing an annealing process for forming a barrier layer formed of a compound of the additive metal and constituent elements of the interlayer dielectric film;
(c) performing surface treatment on the substrate by supplying a vapor of an organic acid or a ketone to the surface of the substrate in a vacuum atmosphere to remove the additive metal or an oxide of the additive metal on the substrate; and
(d) filling copper in the recess on the substrate while keeping the substrate under a vacuum atmosphere.

17. A computer program for executing a semiconductor device manufacturing method on a computer, the method comprising the steps of:
(a) forming an alloy layer of copper and an additive metal along a wall surface of a recess in an interlayer dielectric film;
(b) performing an annealing process for forming a barrier layer formed of a compound of the additive metal and constituent elements of the interlayer dielectric film;
(c) performing surface treatment on the substrate by supplying a vapor of an organic acid or a ketone to the surface of the substrate in a vacuum atmosphere to remove the additive metal or an oxide of the additive metal on the substrate; and
(d) filling copper in the recess on the substrate while keeping the substrate under a vacuum atmosphere.
